(19) United States
(12) Patent Application Publication
(10) Pub. No.: US 2025/0298151 A1
(43) Pub. Date: Sep. 25, 2025

(54) WLAN BASED OSCILLATOR TEMPERATURE FIELD CALIBRATION

(71) Applicant: QUALCOMM Incorporated, San Diego, CA (US)

(72) Inventors: Gregory STEELE, Pleasanton, CA (US); Kapil RAI, Sunnyvale, CA (US); Sandip HOMCHAUDHURI, San Jose, CA (US); Patrick Poon-Cheuk CHAN, San Jose, CA (US)

(21) Appl. No.: 18/610,382

(22) Filed: Mar. 20, 2024

(51) Int. Cl. G01S 19/37; G01S 19/23; G01S 19/25

(52) U.S. Cl. CPC G01S 19/37; G01S 19/23; G01S 19/256

(57) ABSTRACT

Techniques are provided for calibrating a crystal oscillator (XOs) in a global navigation satellite system (GNSS) receiver. An example method for generating XO calibration information includes receiving radio frequency signals from a wireless node, wherein the radio frequency signals include an indication of oscillator temperature information, determining a frequency offset value based at least in part on the radio frequency signals, determining a local oscillator temperature value, determining a frequency correction value based at least in part on the local oscillator temperature value, the frequency offset value, and the indication of oscillator temperature information, and transmitting a calibration report to the wireless node.

### BACKGROUND

The use of wireless devices for many everyday activities is becoming common. Modern wireless devices may make use of one or more wireless communication technologies. For example, a wireless device may communicate in a wireless local area network (WLAN) using a short range communication technology such as WiFi technology, Bluetooth® technology, ultrawideband (UWB) technology, millimeter wave (mmWave) technology, etc. The use of short range communication technologies, such as WiFi and Bluetooth®, in wireless devices has become much more common in the last several years and is regularly used in retail businesses, offices, homes, cars, manufacturing operations, and public gathering places. Access points may be installed to enable data communication between wireless devices and a network. Some access points may enable access to the Internet. Short range communication technologies may be used in ranging and radio frequency sensing operations. In an example, indoor positioning applications may utilize ranging measurements obtained from network stations. The accuracy of ranging and positioning applications may be based at least in part on obtaining the location of the access points. Global Navigation Satellite Systems (GNSS) may be used to obtain the geographic location of an access point. One or more crystal oscillators (XOs) in a GNSS receiver may be used to obtain GNSS signals transmitted by one or more satellites. The frequency of an XO may be impacted by the temperature of the XO. Improving the frequency stability of an XO in a GNSS receiver may improve signal acquisition and decoding.

### SUMMARY

An example method for generating XO calibration information according to the disclosure obtaining an indication of oscillator temperature information associated with one or more radio frequency signals, determining a frequency offset value based at least in part on the one or more radio frequency signals, determining a local oscillator temperature value, determining a frequency correction value based at least in part on the local oscillator temperature value, the frequency offset value, and the indication of oscillator temperature information, and transmitting a calibration report to the wireless node.

An example method for obtaining XO calibration information according to the disclosure includes transmitting a first radio frequency signal to a wireless node at a first time period, determining an oscillator temperature value during the first time period, transmitting a second radio frequency signal to the wireless node at a second time period after the first time period, wherein the second radio frequency signal includes an indication of the oscillator temperature value, and receiving oscillator calibration information from the wireless node.

Items and/or techniques described herein may provide one or more of the following capabilities, as well as other capabilities not mentioned. A wireless node in a network, such as an Access Point (AP) in a wireless local area network (WLAN) may be configured to obtain satellite signals with a GNSS receiver. The frequency of a XO in the GNSS receiver may vary with temperature. An AP may request to initiate a XO calibration procedure with one or more neighboring wireless nodes. A thermal sensor disposed proximate to the XO may be used to determine the temperature of the XO. The AP may transmit a plurality of measurement packets including XO temperature information to a neighboring wireless node. The neighboring wireless node may be configured to measure a frequency offset based on receiving the measurement packets and may obtain local XO temperature information. The neighboring wireless node may utilized the XO temperature information in the measurement packets, the local XO temperature information, and the frequency offset to calculate frequency calibration information. The frequency calibration information may be transmitted to the AP, and the AP may utilize the frequency calibration information to adjust the frequency of the GNSS receiver. The sensitivity of the GNSS receiver may be increased and the acquisition time of GNSS signals may be reduced. Other capabilities may be provided and not every implementation according to the disclosure must provide any, let alone all, of the capabilities discussed.

### BRIEF DESCRIPTION OF THE DRAWINGS

FIG. 1 is a diagram of an example wireless local area network (WLAN).

FIG. 2 is a block diagram of components of an example wireless node or user equipment.

FIG. 3 is a block diagram of components of an example access point.

FIG. 4A is a block diagram of components of an example temperature-compensated crystal oscillator (TCXO).

FIG. 4B is a graph of an example XO with temperature compensation.

FIG. 5 is a diagram of an example XO field calibration procedure.

FIG. 6A is an example message flow for a unidirectional XO field calibration protocol.

FIG. 6B is an example of a partial message flow for a bidirectional XO field calibration protocol.

FIG. 7 is an example XO calibration packet exchange.

FIG. 8 is a process flow diagram of an example method for generating XO calibration information.

FIG. 9 is a process flow diagram of an example method for obtaining XO calibration information.

### DETAILED DESCRIPTION

Techniques are discussed herein for calibrating crystal oscillators (XOs) in global navigation satellite system (GNSS) receivers. In general, a GNSS receiver may require a stable XO to achieve sufficient signal sensitivity and decreased signal acquisition times. A GNSS receiver may be configured to detect GNSS signals by correlating an incoming signal with known pseudo-noise (PN) sequences. There can be differences in carrier and sampling frequency between the GNSS receiver and a desired signal due to the uncertainty of the satellite and receiver XOs as well as the doppler due to satellite and receiver motion. To achieve a strong correlation, the carrier and sampling frequency of the receiver should be close to that of a desired GNSS signal. The GNSS signal level may be much lower than the thermal noise, and thus, a frequency offset may not be estimated directly from the GNSS signal. To acquire the GNSS signal, the receiver may be configured to correlate an input signal with multiple frequency offsets to test which is closest to that of the desired signal. The more uncertainty in frequency offset the more frequencies that the receiver must test. Knowledge of the absolute XO frequency offset may assist in reducing the frequency offset search range, and thus, the acquisition time of a GNSS signal may be reduced.

The stability of the XO may assist in improving the sensitivity of a GNSS receiver. For example, when a GNSS receiver is testing a frequency offset hypothesis, the receiver may be configured to correlate for long periods of time. These periods may be in the range of tens of seconds to detect GNSS signals in an indoor or near indoor environment. If the XO drifts too much while the GNSS receiver is attempting to correlate, then the receiver may be unable to detect the signal. In this sense, the absolute frequency offset may not be as important to receiver sensitivity as compared to the stability of the XO. For example an XO may be stable, but a large uncertainty may enable good sensitivity with long acquisition times. In contrast, an XO with a low initial uncertainty and that is not very stable may enable fast acquisition with poor sensitivity.

The frequency of an XO may vary with temperature. The techniques provided herein improve XO accuracy and stability by compensating for temperature variations. In operation, a wireless node such as an access point (AP) in a wireless local area network (WLAN), may be configured to monitor the temperature of an XO and then adjust the carrier/sampling frequency of the receiver based on the temperature changes. In an example, a GNSS receiver in a mobile device may share an XO with a wireless wide area network (WWAN) radio and may be configured to calibrate a frequency-temperature (FT) response of the XO by measuring the frequency offset of the WWAN radio relative to an network base station as the temperature of the device varies. For example, an AP may be configured to calibrate the temperature characteristics of an XO by using a signal from a WWAN base station as an absolute reference. In another example, a GNSS receiver may not share an XO with a WWAN radio and may be configured to utilize temperature information from neighboring stations to calibrate the XO. Specifically, if there are multiple neighboring WLAN devices in the WLAN network configured with thermistors that are proximate to their respective XOs, then by exchanging XO temperature information and measuring the relative frequency offset, network stations may be configured to calibrate how the XO frequency varies with temperature. In contrast to a WWAN based calibration procedure, which may utilize an absolute reference, exchanges with neighboring WLAN stations may not provide sufficient information to determine an absolute XO frequency versus temperature because neither side of the link is an absolute frequency reference. The calibration procedures provided herein, however, may provide sufficient information to compensate for the instability in the XO with temperature to improve stability over long correlation times (e.g., 1 to 100 seconds). In an example, an initial calibration of the frequency offset at one temperature may be performed by a device manufacturer. Such an initial calibration of an XO at one temperature may be further refined based on the field calibration procedures provided herein. For example, once a GNSS receiver acquires a GNSS signal with a large frequency search span, the receiver may be configured to use the frequency offset determined during the acquisition to refine the manufacturer's calibration of the absolute offset versus temperature. The continued refinements may enable a reduction in the frequency search space in subsequent GNSS signal acquisitions.

Particular aspects of the subject matter described in this disclosure may be implemented to realize one or more of the following potential advantages. A packet exchange protocol between two WLAN devices may enable the WLAN devices to relatively calibrate their respective frequency error characteristics as a function of temperature change. The exchange protocol may be independent of frequency. The XO calibration may improve GNSS signal acquisition time. The calibration exchanges may be beneficial for other of positioning techniques, such as round trip time (RTT) and time of arrival (ToA) measurements. Other advantages may also be realized.

The following description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in other examples.

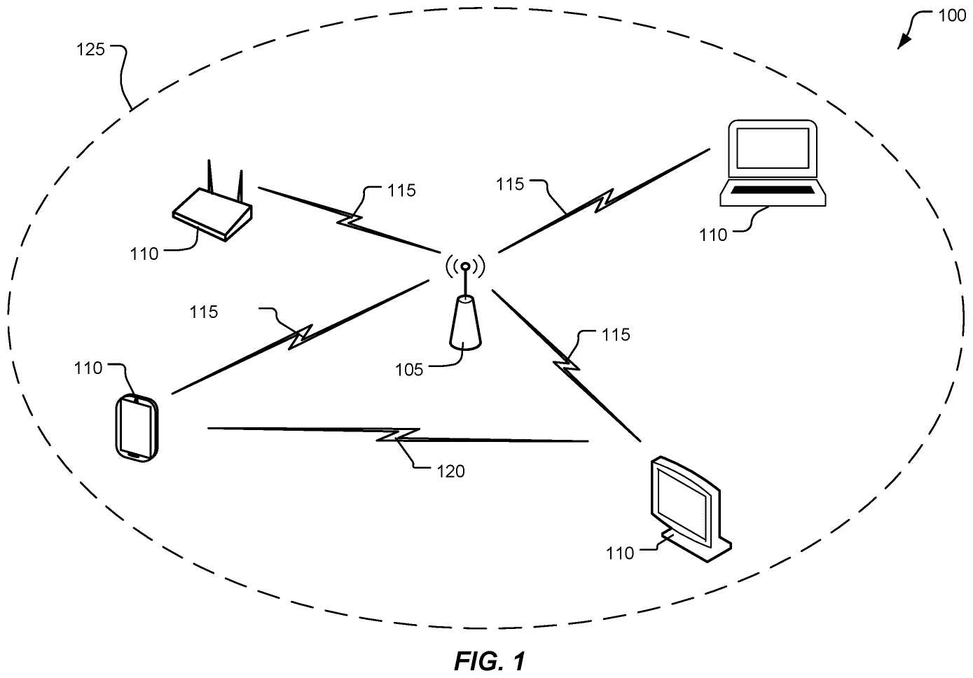

Referring to FIG. 1, a block diagram illustrates an example of a WLAN network 100 such as, e.g., a network implementing IEEE 802.11 and IEEE 802.15 families of standards. The WLAN network 100 may include an access point (AP) 105 and one or more wireless devices 110 or stations (STAs) 110, such as mobile stations, head mounted devices (HMDs), personal digital assistants (PDAs), asset tracking devices, other handheld devices, netbooks, notebook computers, tablet computers, laptops, display devices (e.g., TVs, computer monitors, etc.), printers, IoT devices, asset tags, key fobs, vehicles, etc. The AP 105 and the wireless devices 110 may be WiFi, Bluetooth®, and/or UWB capable devices. While one AP 105 is illustrated, the WLAN network 100 may have multiple APs 105. Each of the wireless devices 110, which may also be referred to as mobile stations (MSs), mobile devices, access terminals (ATs), user equipment(s) (UE), wireless nodes, wireless devices, subscriber stations (SSs), or subscriber units, may associate and communicate with an AP 105 via a communication link 115. Each AP 105 has a geographic coverage area 125 such that wireless devices 110 within that area can typically communicate with the AP 105. The wireless devices 110 may be dispersed throughout the geographic coverage area 125. Each wireless device 110 may be stationary or mobile.

A wireless device 110 can be covered by more than one AP 105 and can therefore associate with one or more APs 105 at different times. A single AP 105 and an associated set of stations may be referred to as a basic service set (BSS). An extended service set (ESS) is a set of connected BSSs. A distribution system (DS) is used to connect APs 105 in an extended service set. A geographic coverage area 125 for an access point 105 may be divided into sectors making up a portion of the coverage area. The WLAN network 100 may include access points 105 of different types (e.g., metropolitan area, home network, etc.), with varying sizes of coverage areas and overlapping coverage areas for different technologies. In other examples, other wireless devices can communicate with the AP 105.

While the wireless devices 110 may communicate with each other through the AP 105 using communication links 115, each wireless device 110 may also communicate directly with one or more other wireless devices 110 via a direct wireless link 120. Two or more wireless devices 110 may communicate via a direct wireless link 120 when both wireless devices 110 are in the AP geographic coverage area 125 or when one or neither wireless device 110 is within the AP geographic coverage area 125. Examples of direct wireless links 120 may include WiFi Direct connections, connections established by using a WiFi Tunneled Direct Link Setup (TDLS) link, 5G-NR sidelink, PC5, UWB, Bluetooth®, and other P2P group connections. The wireless devices 110 in these examples may communicate according to the WLAN radio and baseband protocol including physical and MAC layers from IEEE 802.11 and IEEE 802.15, and their various versions. For example, the one or more of the wireless devices 110 and the AP 105 may be configured to utilize WiFi, Bluetooth®, and/or UWB signals for communications and/or positioning applications.

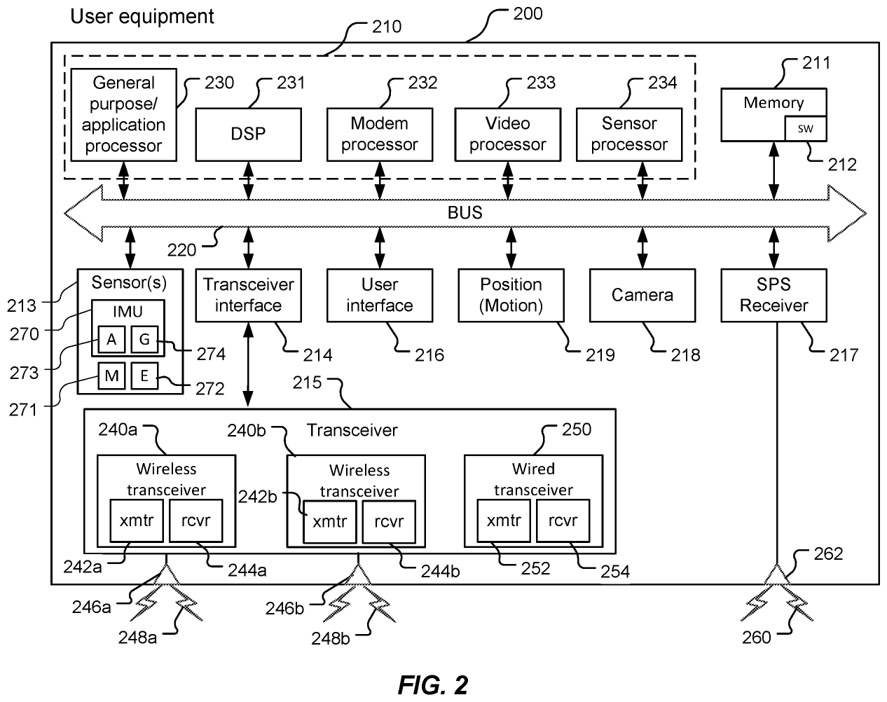

Referring also to FIG. 2, a UE 200 is an example of the wireless devices 110 and comprises a computing platform including a processor 210, memory 211 including software (SW) 212, one or more sensors 213, a transceiver interface 214 for a transceiver 215 (including one or more wireless transceivers such as a first wireless transceiver 240a, a second wireless transceiver 240b, and optionally a wired transceiver 250), a user interface 216, a Satellite Positioning System (SPS) receiver 217, a camera 218, and a position (motion) device 219. The processor 210, the memory 211, the sensor(s) 213, the transceiver interface 214, the user interface 216, the SPS receiver 217, the camera 218, and the position (motion) device 219 may be communicatively coupled to each other by a bus 220 (which may be configured, e.g., for optical and/or electrical communication). One or more of the shown apparatuses (e.g., the camera 218, the position (motion) device 219, and/or one or more of the sensor(s) 213, etc.) may be omitted from the UE 200. The processor 210 may include one or more hardware devices, e.g., a central processing unit (CPU), a microcontroller, an application specific integrated circuit (ASIC), etc. The processor 210 may comprise multiple processors including a general-purpose/application processor 230, a Digital Signal Processor (DSP) 231, a modem processor 232, a video processor 233, and/or a sensor processor 234. One or more of the processors 230-234 may comprise multiple devices (e.g., multiple processors). For example, the sensor processor 234 may comprise, e.g., processors for radio frequency (RF) sensing and ultrasound. The modem processor 232 may support dual SIM/dual connectivity (or even more SIMs). For example, a SIM (Subscriber Identity Module or Subscriber Identification Module) may be used by an Original Equipment Manufacturer (OEM), and another SIM may be used by an end user of the UE 200 for connectivity. The memory 211 is a non-transitory storage medium that may include random access memory (RAM), flash memory, disc memory, and/or read-only memory (ROM), etc. The memory 211 stores the software (which may also include firmware) 212 which may be processor-readable, processor-executable software code containing instructions that are configured to, when executed, cause the processor 210 to perform various functions described herein. Alternatively, the software 212 may not be directly executable by the processor 210 but may be configured to cause the processor 210, e.g., when compiled and executed, to perform the functions. The description may refer to the processor 210 performing a function, but this includes other implementations such as where the processor 210 executes software and/or firmware. The description may refer to the processor 210 performing a function as shorthand for one or more of the processors 230-234 performing the function. The description may refer to the UE 200 performing a function as shorthand for one or more appropriate components of the UE 200 performing the function. The processor 210 may include a memory with stored instructions in addition to and/or instead of the memory 211. Functionality of the processor 210 is discussed more fully below.

The configuration of the UE 200 shown in FIG. 2 is an example and not limiting of the disclosure, including the claims, and other configurations may be used. For example, an example configuration of the UE includes one or more of the processors 230-234 of the processor 210, the memory 211, and the wireless transceivers 240a-b. Other example configurations include one or more of the processors 230-234 of the processor 210, the memory 211, the wireless transceivers 240a-b, and one or more of the sensor(s) 213, the user interface 216, the SPS receiver 217, the camera 218, the PMD 219, and/or the wired transceiver 250. Other configurations may not include all of the components of the UE 200. For example, an IoT device may include more wireless transceivers 240a-b, the memory 211 and a general-purpose processor 230. A multi-link device may simultaneously utilize the first wireless transceiver 240a on a first link using a first frequency band, and the second wireless transceiver 240b on a second link using a second frequency band. Additional transceivers may also be used for additional links and frequency bands and radio access technologies.

The UE 200 may comprise the modem processor 232 that may be capable of performing baseband processing of signals received and down-converted by the transceiver 215 and/or the SPS receiver 217. The modem processor 232 may perform baseband processing of signals to be upconverted for transmission by the transceiver 215. Also or alternatively, baseband processing may be performed by the general-purpose processor 230 and/or the DSP 231. Other configurations, however, may be used to perform baseband processing.

The UE 200 may include the sensor(s) 213 that may include, for example, an Inertial Measurement Unit (IMU) 270, one or more magnetometers 271, and/or one or more environment sensors 272. The IMU 270 may comprise one or more inertial sensors, for example, one or more accelerometers 273 (e.g., collectively responding to acceleration of the UE 200 in three dimensions) and/or one or more gyroscopes 274. The magnetometer(s) may provide measurements to determine orientation (e.g., relative to magnetic north and/or true north) that may be used for any of a variety of purposes, e.g., to support one or more compass applications. The environment sensor(s) 272 may comprise, for example, one or more temperature sensors, one or more barometric pressure sensors, one or more ambient light sensors, one or more camera imagers, and/or one or more microphones, etc. The sensor(s) 213 may generate analog and/or digital signals indications of which may be stored in the memory 211 and processed by the DSP 231 and/or the general-purpose processor 230 in support of one or more applications such as, for example, applications directed to positioning and/or navigation operations.

The sensor(s) 213 may be used in relative location measurements, relative location determination, motion determination, etc. Information detected by the sensor(s) 213 may be used for motion detection, relative displacement, dead reckoning, sensor-based location determination, and/or sensor-assisted location determination. The sensor(s) 213 may be useful to determine whether the UE 200 is fixed (stationary) or mobile. In another example, for relative positioning information, the sensors/IMU can be used to determine the angle and/or orientation of the other device with respect to the UE 200, etc.

The IMU 270 may be configured to provide measurements about a direction of motion and/or a speed of motion of the UE 200, which may be used in relative location determination. For example, the one or more accelerometers 273 and/or the one or more gyroscopes 274 of the IMU 270 may detect, respectively, a linear acceleration and a speed of rotation of the UE 200. The linear acceleration and speed of rotation measurements of the UE 200 may be integrated over time to determine an instantaneous direction of motion as well as a displacement of the UE 200. The instantaneous direction of motion and the displacement may be integrated to track a location of the UE 200. For example, a reference location of the UE 200 may be determined, e.g., using the SPS receiver 217 (and/or by some other means) for a moment in time and measurements from the accelerometer(s) 273 and gyroscope(s) 274 taken after this moment in time may be used in dead reckoning to determine present location of the UE 200 based on movement (direction and distance) of the UE 200 relative to the reference location.

The magnetometer(s) 271 may determine magnetic field strengths in different directions which may be used to determine orientation of the UE 200. For example, the orientation may be used to provide a digital compass for the UE 200. The magnetometer(s) 271 may include a two-dimensional magnetometer configured to detect and provide indications of magnetic field strength in two orthogonal dimensions. Also or alternatively, the magnetometer(s) 271 may include a three-dimensional magnetometer configured to detect and provide indications of magnetic field strength in three orthogonal dimensions. The magnetometer(s) 271 may provide means for sensing a magnetic field and providing indications of the magnetic field, e.g., to the processor 210.

The transceiver 215 may include wireless transceivers 240a-b and a wired transceiver 250 configured to communicate with other devices through wireless connections and wired connections, respectively. In an example, each of the wireless transceivers 240a-b may include respective transmitters 242a-b and receivers 244a-b coupled to one or more respective antennas 246a-b for transmitting and/or receiving wireless signals 248a-b and transducing signals from the wireless signals 248a-b to wired (e.g., electrical and/or optical) signals and from wired (e.g., electrical and/or optical) signals to the wireless signals 248a-b. Thus, the transmitters 242a-b may be the same transmitter, or may include multiple transmitters that may be discrete components or combined/integrated components, and/or the receivers 244a-b may be the same receiver, or may include multiple receivers that may be discrete components or combined/integrated components. The wireless transceivers 240a-b may be configured to communicate signals (e.g., with access points and/or one or more other devices) according to a variety of radio access technologies (RATs) such as 5G New Radio (NR), GSM (Global System for Mobiles), UMTS (Universal Mobile Telecommunications System), AMPS (Advanced Mobile Phone System), CDMA (Code Division Multiple Access), WCDMA (Wideband CDMA), LTE (Long-Term Evolution), LTE Direct (LTE-D), 3GPP LTE-V2X (PC5), IEEE 802.11 (including IEEE 802.11ax and 802.11be), WiFi, WiFi Direct (WiFi-D), Bluetooth®, IEEE 802.15 (UWB), Zigbee etc. The wireless transceivers 240a-b may be configured to obtain signal strength measurements for RF signals associated with one or more RATS. The wired transceiver 250 may include a transmitter 252 and a receiver 254 configured for wired communication. The transmitter 252 may include multiple transmitters that may be discrete components or combined/integrated components, and/or the receiver 254 may include multiple receivers that may be discrete components or combined/integrated components. The wired transceiver 250 may be configured, e.g., for optical communication and/or electrical communication. The transceiver 215 may be communicatively coupled to the transceiver interface 214, e.g., by optical and/or electrical connection. The transceiver interface 214 may be at least partially integrated with the transceiver 215.

The user interface 216 may comprise one or more of several devices such as, for example, a speaker, microphone, display device, vibration device, keyboard, touch screen, etc. The user interface 216 may include more than one of any of these devices. The user interface 216 may be configured to enable a user to interact with one or more applications hosted by the UE 200. For example, the user interface 216 may store indications of analog and/or digital signals in the memory 211 to be processed by DSP 231 and/or the general-purpose processor 230 in response to action from a user. Similarly, applications hosted on the UE 200 may store indications of analog and/or digital signals in the memory 211 to present an output signal to a user. The user interface 216 may include an audio input/output (I/O) device comprising, for example, a speaker, a microphone, digital-to-analog circuitry, analog-to-digital circuitry, an amplifier and/or gain control circuitry (including more than one of any of these devices). Other configurations of an audio I/O device may be used. Also or alternatively, the user interface 216 may comprise one or more touch sensors responsive to touching and/or pressure, e.g., on a keyboard and/or touch screen of the user interface 216. In an example, the user interface 216 may include one or more biometric sensors configured to obtain biometric information from a user. For example, the biometric sensors may include a fingerprint capture device, a microphone (for voice input), the camera 218 (e.g., for facial recognition, iris detection), a display (e.g., for finger swipe recognition) or other such sensors. The IMU 270 may be configured to obtain motion data to determine biometric information such as the user's gait or step length. Other sensors in the UE 200 may also be used to obtain biometric information from a user.

The SPS receiver 217 (e.g., a Global Positioning System (GPS) receiver) may be capable of receiving and acquiring SPS signals 260 via an SPS antenna 262. The antenna 262 is configured to transduce the SPS signals 260 to wired signals, e.g., electrical or optical signals, and may be integrated with one or more of the antennas 246a-b. The SPS receiver 217 may be configured to process, in whole or in part, the acquired SPS signals 260 for estimating a location of the UE 200. For example, the SPS receiver 217 may be configured to determine location of the UE 200 by trilateration using the SPS signals 260. The general-purpose processor 230, the memory 211, the DSP 231 and/or one or more specialized processors (not shown) may be utilized to process acquired SPS signals, in whole or in part, and/or to calculate an estimated location of the UE 200, in conjunction with the SPS receiver 217. The memory 211 may store indications (e.g., measurements) of the SPS signals 260 and/or other signals (e.g., signals acquired from the wireless transceivers 240a-b) for use in performing positioning operations. For example, the positioning operations may be based on RSSI measurements. The general-purpose processor 230, the DSP 231, and/or one or more specialized processors, and/or the memory 211 may provide or support a location engine for use in processing measurements to estimate a location of the UE 200.

The UE 200 may include the camera 218 for capturing still or moving imagery. The camera 218 may comprise, for example, an imaging sensor (e.g., a charge coupled device or a CMOS imager), a lens, analog-to-digital circuitry, frame buffers, etc. Additional processing, conditioning, encoding, and/or compression of signals representing captured images may be performed by the general-purpose processor 230 and/or the DSP 231. Also or alternatively, the video processor 233 may perform conditioning, encoding, compression, and/or manipulation of signals representing captured images. The video processor 233 may decode/decompress stored image data for presentation on a display device (not shown), e.g., of the user interface 216.

The position (motion) device (PMD) 219 may be configured to determine a position and possibly motion of the UE 200. For example, the PMD 219 may communicate with, and/or include some or all of, the SPS receiver 217. The PMD 219 may also or alternatively be configured to determine location of the UE 200 using terrestrial-based signals (e.g., at least some of the wireless signals 248a-b) for trilateration or mulilateration, for assistance with obtaining and using the SPS signals 260, or both. The PMD 219 may be configured to use one or more other techniques (e.g., relying on the UE's self-reported location (e.g., part of the UE's position beacon)) for determining the location of the UE 200, and may use a combination of techniques (e.g., SPS and terrestrial positioning signals) to determine the location of the UE 200. The PMD 219 may include one or more of the sensors 213 (e.g., gyroscope(s), accelerometer(s), magnetometer(s), etc.) that may sense orientation and/or motion of the UE 200 and provide indications thereof that the processor 210 (e.g., the general-purpose processor 230 and/or the DSP 231) may be configured to use to determine motion (e.g., a velocity vector and/or an acceleration vector) of the UE 200. The PMD 219 may be configured to provide indications of uncertainty and/or error in the determined position and/or motion. In an example the PMD 219 may be referred to as a Positioning Engine (PE), and may be performed by the general-purpose processor 230. For example, the PMD 219 may be a logical entity and may be integrated with the general-purpose processor 230 and the memory 211.

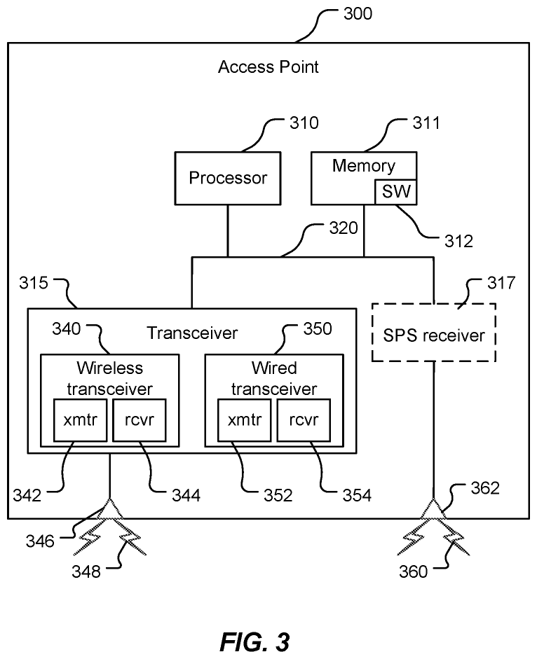

Referring also to FIG. 3, an example of an access point (AP) 300 such as the AP 105 comprises a computing platform including a processor 310, memory 311 including software (SW) 312, a transceiver 315, and (optionally) an SPS receiver 317. The processor 310, the memory 311, the transceiver 315, and the SPS receiver 317 may be communicatively coupled to each other by a bus 320 (which may be configured, e.g., for optical and/or electrical communication). One or more of the shown apparatuses (e.g., a wireless interface and/or the SPS receiver 317) may be omitted from the AP 300. In an example, the SPS receiver 317 may be configured similarly to the SPS receiver 217 to be capable of receiving and acquiring SPS signals 360 via an SPS antenna 362. The SPS receiver 317 may include a XO and a thermal sensor. Other configurations for sharing receive chains between the wireless transceiver and the SPS receiver 317 as described herein may also be used. The processor 310 may include one or more intelligent hardware devices, e.g., a central processing unit (CPU), a microcontroller, an application specific integrated circuit (ASIC), etc. The processor 310 may comprise multiple processors (e.g., including a general-purpose/application processor, a DSP, a modem processor, a video processor, and/or a sensor processor as shown in FIG. 2). The memory 311 is a non-transitory storage medium that may include random access memory (RAM)), flash memory, disc memory, and/or read-only memory (ROM), etc. The memory 311 stores the software 312 which may be processor-readable, processor-executable software code containing instructions that are configured to, when executed, cause the processor 310 to perform various functions described herein. Alternatively, the software 312 may not be directly executable by the processor 310 but may be configured to cause the processor 310, e.g., when compiled and executed, to perform the functions. The description may refer to the processor 310 performing a function, but this includes other implementations such as where the processor 310 executes software and/or firmware. The description may refer to the processor 310 performing a function as shorthand for one or more of the processors contained in the processor 310 performing the function. The processor 310 may include a memory with stored instructions in addition to and/or instead of the memory 311. Functionality of the processor 310 is discussed more fully below.

The transceiver 315 may include a wireless transceiver 340 and a wired transceiver 350 configured to communicate with other devices through wireless connections and wired connections, respectively. For example, the wireless transceiver 340 may include a transmitter 342 and receiver 344 coupled to one or more antennas 346 for transmitting (e.g., on one or more uplink channels) and/or receiving (e.g., on one or more downlink channels) wireless signals 348 and transducing signals from the wireless signals 348 to wired (e.g., electrical and/or optical) signals and from wired (e.g., electrical and/or optical) signals to the wireless signals 348. Thus, the transmitter 342 may include multiple transmitters that may be discrete components or combined/integrated components, and/or the receiver 344 may include multiple receivers that may be discrete components or combined/integrated components. The wireless transceiver 340 may be configured to communicate signals (e.g., with the UE 200, one or more other UEs, and/or one or more other devices) according to a variety of radio access technologies (RATs) such as IEEE 802.11 (including IEEE 802.11ax and 802.11be), WiFi, WiFi Direct (WiFi-D), Bluetooth®, IEEE 802.15 (UWB), Zigbee etc. The wired transceiver 350 may include a transmitter 352 and a receiver 354 configured for wired communication. The transmitter 352 may include multiple transmitters that may be discrete components or combined/integrated components, and/or the receiver 354 may include multiple receivers that may be discrete components or combined/integrated components. The wired transceiver 350 may be configured, e.g., for optical communication and/or electrical communication.

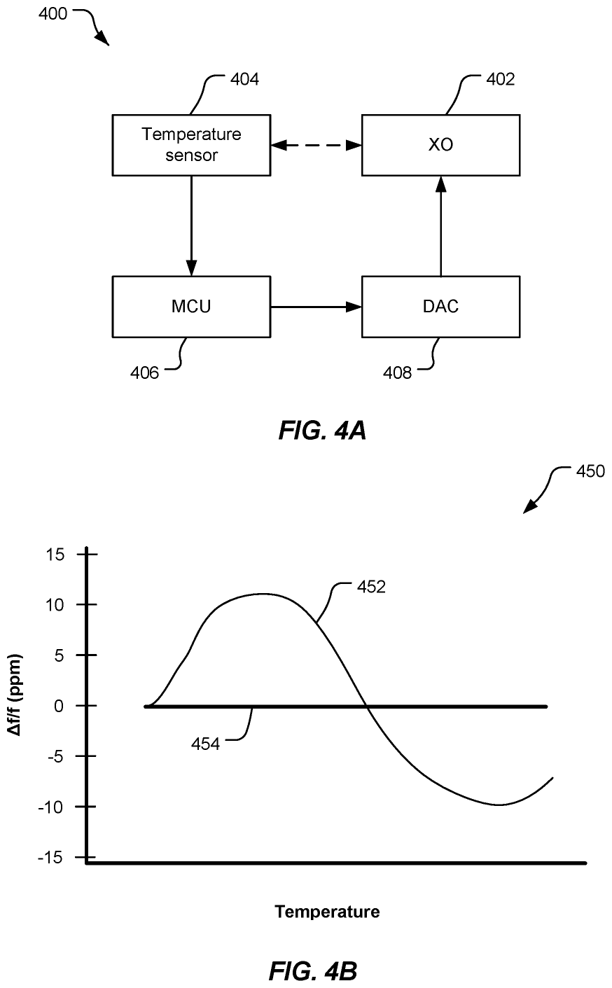

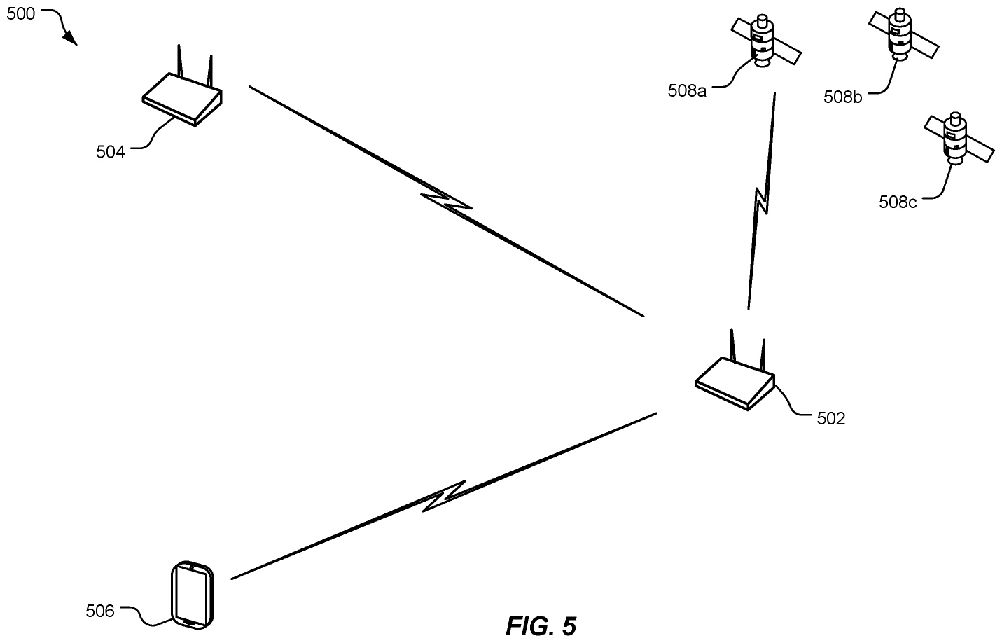

Referring to FIG. 4A, a block diagram of components of an example TCXO 400 are shown. The TCXO may be included in a transceiver or receiver such as the transceiver 215 in the UE 200, and/or the transceiver 315 in the AP 300. In an example, a SPS receiver may be configured with a TCXO 400. The TCXO 400 is an example solution for controlling the thermal hysteresis of a crystal oscillator 402. The TCXO 400 includes a temperature sensor 404 (e.g., a thermistor), a micro Controller Unit (MCU) 406, and a digital-to-analog converter (DAC) 408. In an example, the MCU 406 is configured to communicate with the temperature sensor 404 and to set the DAC 408 voltage according to the measured temperature to adjust the output frequency of the TCXO 400. The MCU 406 may include a compensation table that corresponds to the temperature and the DAC voltages to adjust the TCXO output frequency. Referring to FIG. 4B, a graph 450 of an example XO field calibration procedure is shown. The graph 450 is an example of a frequency-temperature (FT) response of an XO. The graph 450 may be a visual example of components of a compensation table for adjusting the TCXO output frequency. A pre-compensation plot 452 illustrates the variation in frequency based on temperature, and a post-compensation plot 454 illustrates the output frequency after compensation for different temperatures. The plots 452, 454 are examples and not limitations as other XOs may have different temperature/frequency profiles.

The techniques provided herein may to utilized with receivers which are not equipped with a TCXO including a MCU. For example, a GNSS receiver or AP may be configured without a MCU to reduce cost and/or form factors. Temperature readings from neighboring stations may be used by a GNSS receiver, for example, to compensate for the temperature of the local XO.

Referring to FIG. 5, a diagram 500 of an example XO field calibration procedure is shown. The diagram 500 includes a first AP 502 with a GNSS receiver configured to receive RF signals from one or more satellite vehicles (SVs) 508a, 508b, 508c. The first AP 502 is configured to communicate with one or more neighboring stations, such as a second AP 504 and/or a UE 506. The second AP 504 and/or the UE 506 may include a thermistor, or other temperature sensor, configured to determine a temperature proximate to their respective XOs. In an example, the first AP 502 is configured with a thermistor proximate to the XO. In operation, the XO field calibration may utilize one wireless node (e.g., AP, UE, etc.) transmitting multiple packets to another wireless node. For example, the second AP 502 may transmit packets to the first AP 502. The second AP 504 (i.e., the transmitting device) may be configured to measure the temperature of its XO during transmission and include the temperature in the data of a subsequent transmitted packet. The first AP 502 (i.e., a receiving device) may be configured to measure the frequency offset between the second AP 504 and the first AP 502, as well as the temperature of XO in the first AP 502 at the time the first AP 502 measures the frequency offset. The first AP 502 may utilize the results of multiple such measurements to estimate the frequency-temperature (FT) response of the XOs in both APs 502, 504. The FT response information may be utilized as an offset when acquiring signals from the SVs 508a-c.

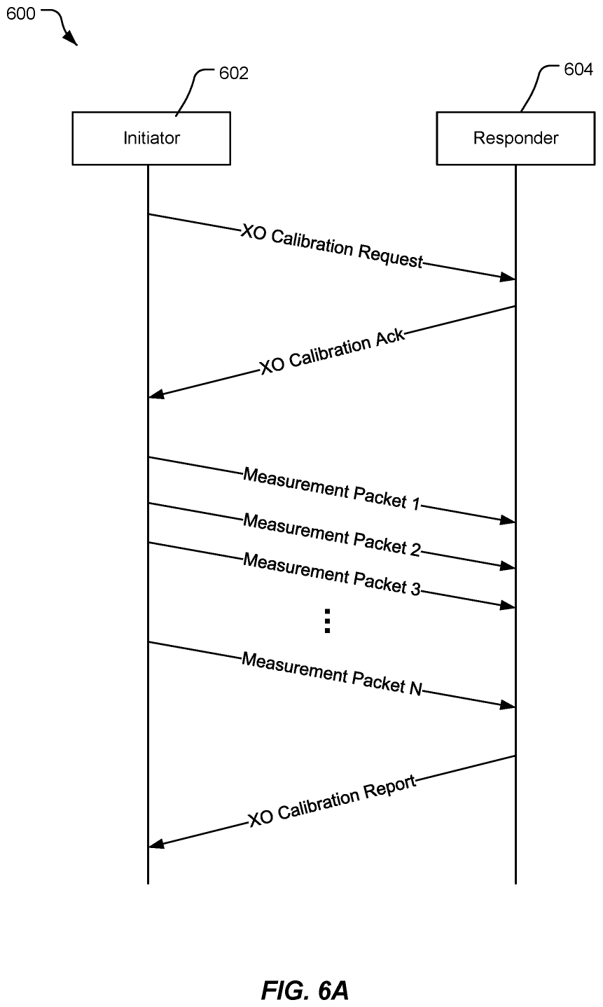

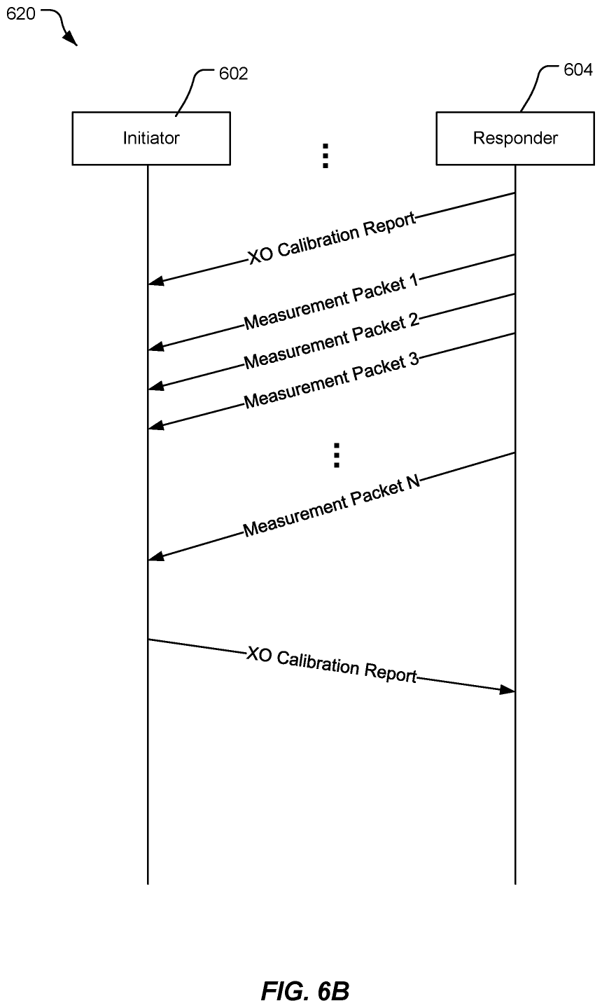

Referring to FIG. 6A, an example message flow 600 for a unidirectional XO field calibration protocol is shown. The message flow 600 includes an initiator 602 and a responder 604. In an example, the initiator 602 and the responder 604 may be the first and second APs 502, 504. Other wireless nodes may also be the initiator 602 or responder 604. In general, the accuracy of an XO calibration may be improved when there is variation in the device temperature over multiple measurements. Transmitting over-the-air (OTA) packets may be used to generate heat within a device, which may cause a temperature change in an XO in the device. For example, the initiator 602 may desire to calibrate its own XO FT response and may be configured to transmit measurement packets to achieve a desired temperature variation. The message flow 600 may include a XO calibration request message transmitted from the initiator 602 to the responder 604. The XO calibration request message may include a number of measurement packets to be used in the calibration operation. In an example, the XO calibration request message may include an indication on whether the measurement process will be bi-directional. The responder 604 may be configured to send a XO calibration acknowledgement frame to indicate that the responder 604 is willing to conduct the calibration scheme with the parameters specified in the XO calibration request message. The initiator 602 then transmits a sequence of measurement packets (e.g., measurement packets 1, 2, 3, etc.). In an example, measurement packet k includes a temperature measurement that was conducted during the transmission of measurement packet k−1. Once the specified number of measurement packets has been sent (e.g., measurement packet N), the responder 604 may be configured to send a XO calibration report packet which includes information with regards to the state of the calibration.

Referring to FIG. 6B, with further reference to FIG. 6A, a partial message flow 620 for a bidirectional XO field calibration protocol is shown. The message flow 620 may be a continuation of the message flow 600. The message flow 620 may be useful in a scenario in which the initiator 602 wants to collect measurements while it is cooling down after transmitting the initial measurement packets. The bidirectional measurement flow 620 may also be useful to simultaneously calibrate both sides of a communication link. In this use case, it may be useful for the responder 604 to signal a desire for the bidirectional test in the XO calibration acknowledgement message. The message flow 620 may begin similar to the unidirectional case described in FIG. 6A. After the responder 604 sends the XO calibration report packet, the responder 604 may then transmit N measurement packets. In an example, the XO calibration report sent by the responder 604 may include information of the estimation process. Once the responder 604 has sent the last of the measurement packets (e.g., measurement packet N), the initiator 602 may be configured to send the responder 604 a XO calibration report message including the results of the estimation process.

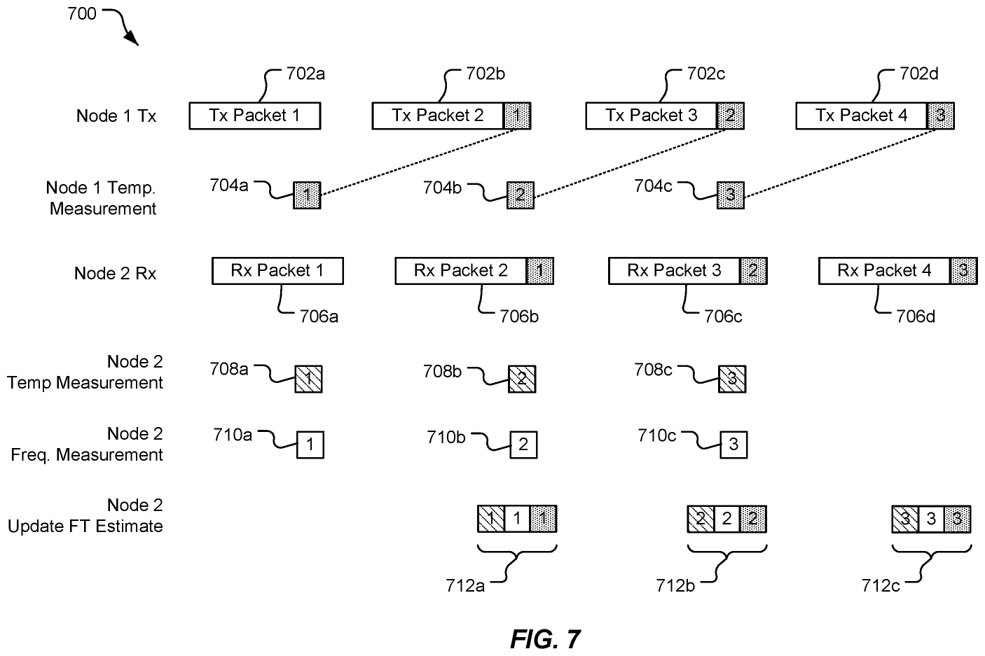

Referring to FIG. 7, an example XO calibration packet exchange 700 is shown. The exchange 700 includes four measurement packets such as described in the example message flows 600, 620. The exchange 700 depicts a sequence of measurement packets for an XO calibration scheme. A first node (e.g., the initiator 602) may be configured to transmit a first packet 702a, a second packet 702b, a third packet 702c and a fourth packet 702d to a second node (e.g., the responder 604). The number of data packets is an example and not a limitation. The first node is configured to obtain temperature information for the XO in the first node. A first temperature value 704a may be obtained when the first packet 702a is being transmitted, a second temperature value 704b may be obtained when the second packet 702b is being transmitted, and a third temperature value 704c may be obtained when the third packet 702c is being transmitted. The first temperature value 704a may be included in the payload of the second packet 702b, the second temperature value 704b may be included in the payload of the third packet 702c, and the third temperature value 704c may be included in the payload of the fourth packet 702d.

The second node may receive the packets transmitted by the first node. For example a first receive packet 706a based on the first packet 702a, a second receive packet 706b (including the first temperature value 704a), a third receive packet 706c (including the second temperature value 704b), and a fourth receive packet 706d (including the third temperature value 704c). The second node may be configured to measure the temperature of its XO as well as the frequency offset during reception of the first packet. It stores this information until reception of the second packet is complete. For example, a first XO temperature 708a and a first frequency offset 710a. Once the second packet is received (e.g., the second receive packet 706b), the second node has the following information from the first measurement packet: the temperature of first node's XO during packet 1 (e.g., the first temperature value 704a), the temperature of the second node's XO during the first packet (e.g., the first XO temperature 708a), and the frequency offset between the two nodes during packet 1 (e.g., the first frequency offset 710a). The procedure may continue for the third and fourth packets 702c, 702d, such that the second node will have a second XO temperature 708b, a second frequency offset 710b, a third XO temperature 708c, and a third frequency offset 710c. Thus, sequences of measurements 712a, 712b, 712c may be obtained for additional packets. In operation, the first and second nodes may be configured to send their temperature measurement relative to some reference temperature measurement tᵢ′. Thus, after the reception of the second receive packet 706b, the second node device will have:

$$Δ f = {f}_{2} ( Δ {t}_{2} ) - {f}_{1} ( Δ {t}_{1} ) \qquad ( 1 )$$

$$Δ {t}_{1} = {t}_{1} - {t}_{1}^{′} \qquad ( 2 )$$

$$Δ {t}_{2} = {t}_{2} - {t}_{2}^{′} \qquad ( 3 )$$

The computation involved with estimating the FT response for both XOs from such sequences of measurements may be described with the following form for the frequency-temperature characteristic of each XO:

$${f}_{i} ( t ) = {C}_{0 , i} + {C}_{1 , i} ( t - {t}_{i}^{′} ) + {{C}_{2 , i} ( t - {t}_{i}^{′} )}^{2} + {{C}_{3 , i} ( t - {t}_{i}^{′} )}^{3} \qquad ( 4 )$$

Where i indexes over the network nodes, and tᵢ′ is the temperature measurement reference point of each node. As described in FIG. 7 and the paragraph above, the receiving device will have a sequence of frequency offset and temperature measurements (e.g., 712a, 712b, 712c). A least squares solution may be defined, such as the following:

$${u}^{′} = [ \begin{matrix}1 & - 1 & Δ {t}_{2} & - Δ {t}_{1} & Δ {t}_{2}^{2} & - Δ {t}_{1}^{2} & Δ {t}_{2}^{3} & - Δ {t}_{1}^{3}\end{matrix} ] \qquad ( 5 )$$

$${c}^{′} = [ \begin{matrix}{C}_{0 , 2} & {C}_{0 , 1} & {C}_{1 , 2} & {C}_{1 , 1} & {C}_{2 , 2} & {C}_{2 , 1} & {C}_{3 , 2} & {C}_{3 , 1}\end{matrix} ] \qquad ( 6 )$$

The FT response model in equation (4) is applied. The frequency offset and temperature measurements are related to the FT response parameters by the following equation:

$$Δ f = {u}^{′} c \qquad ( 7 )$$

The XO calibration computation involves determining a set of parameters c that solves:

$${min}_{c} {\sum }_{k} {‖ Δ {f}_{k} - {u}_{k}^{′} c ‖}^{2} \qquad ( 8 )$$

This is a least-squares problem with the solution given by:

$$c = {( U * U )}^{- 1} U * Δ f \qquad ( 9 )$$

In which:

$$U = [ \begin{matrix}{u}_{1}^{′} \\ {u}_{2}^{′} \\ ⋮ \\ {u}_{k}\end{matrix} ] \qquad ( 10 )$$

$$and ,$$

$$Δ f = [ \begin{matrix}Δ {f}_{1} \\ Δ {f}_{2} \\ ⋮ \\ Δ {f}_{k}\end{matrix} ] \qquad ( 11 )$$

The matrix U may be rank deficient since column 2 is −1 times column 1. Any C_{2,0} and C_{1,0} that satisfy C_{2,0}=C_{1,0} may be part of the solution that minimizes equation (8). That is, the absolute frequency (i.e. C_{2,0} and C_{1,0}) of either of the device's XO at the reference temperature using this calibration scheme may not be determined. This procedure, however, may be used to estimate C_{2,n} and C_{1,n} for n>0. The following section describes temperature compensation using the derivative information.

Since the calibration procedure and parameter estimation involves multiple measurements over time, a recursive algorithm may be utilized to solve (8). For example, an exponentially-weighted regularized least-squares approach may be used.

$${min}_{c} [ {λ}^{N + 1} c * π c + {\sum }_{j = 0}^{N} {λ}^{N - j} {\vert Δ {f}_{j} - {u}_{j}^{′} c \vert}^{2} ] \qquad ( 12 )$$

A recursive solution would provide an update each time we obtain a new Δf and u′=[1 −1 Δt₂−Δt₁ Δt₂² −Δt₁² Δt₂³ −Δt₁³]. The recursions may be expressed with given by the following state equations:

$$γ = \frac{1}{1 + {λ}^{- 1} {u}^{′} Pu} \qquad ( 13 )$$

$$g = {λ}^{- 1} Pu γ \qquad ( 14 )$$

$$c = c + g [ Δ f - {u}^{′} c ] \qquad ( 15 )$$

$$P = {λ}^{- 1} P - g {g}^{′} / γ \qquad ( 16 )$$

In the protocol sequence described in FIGS. 6A, 6B, and 7, RLS state information (i.e., γ, g, c, and P) may be included in the first packet of the sequence (e.g., the first packet 702a), and/or in an XO calibration report. In this manner the estimate of the FT response of both devices may be updated over multiple measurement sequences.

In the XO temperature field calibration scheme above, an XO with frequency temperature response described by equation (4) may be used to estimate Cₖ for k>0. The frequency correction of the XO during GNSS receive operations may be computed using this information. In an example, periodic/regular temperature measurements (e.g., 10 ms, 100 ms, 500 ms, etc.) may be during GNSS receive operations. As used in the equations below, a first temperature measurement may be indicated by t″ and an unknown frequency offset of the XO relative to the GNSS signal may be referred to f₀. An objective of the XO temperature compensation processes is to determine a frequency change of the XO relative to f₀. For example the frequency change relative to f₀ may be compensated to effectively keep the frequency stable over a GNSS signal acquisition process.

The FT parameters Cₖ for k>0 may be defined in terms of the reference temperature measurement t′. These coefficients may be converted to new coefficients Cₖ″ defined in terms of t″. That is:

$$f ( t ) = {\sum }_{k} {{C}_{k} ( t - {t}^{′} )}^{k} = {\sum }_{k} {{C}_{k}^{′′} ( t - {t}^{′′} )}^{k} \qquad ( 17 )$$

Cₖ″ and Cₖ may be related by equating the derivatives of the two expansions evaluated at t=t″. That is:

$${C}_{3}^{′′} = {C}_{3} \qquad ( 18 )$$

$${C}_{2}^{′′} = {C}_{2} + 3 {C}_{3} ( {t}^{′′} - {t}^{′} ) \qquad ( 19 )$$

$${C}_{1}^{′′} = {C}_{1} + 2 {C}_{2} ( {t}^{′′} - {t}^{′} ) + 3 {{C}_{3} ( {t}^{′′} - {t}^{′} )}^{2} \qquad ( 20 )$$

The XO frequency temperature response during GNSS receive operations is:

$$f ( t ) = {f}_{0} + {\sum }_{k = 1}^{3} {{C}_{k}^{′′} ( t - {t}^{′′} )}^{k} \qquad ( 21 )$$

In an effort to keep the frequency close to the initial frequency offset f₀, the following correction may be applied during GNSS receive operations based on the temperature measurements t.

$${f}_{correction} = - {\sum }_{k = 1}^{3} {{C}_{k}^{′′} ( t - {t}^{′′} )}^{k} \qquad ( 22 )$$

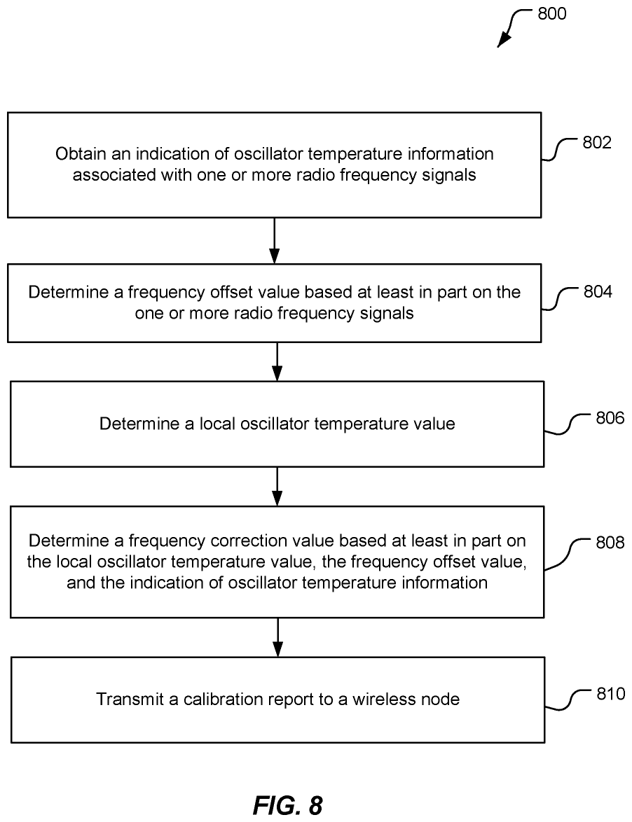

Referring to FIG. 8, with further reference to FIGS. 1-7, a method 800 for generating XO calibration information includes the stages shown. The method 800 is, however, an example and not limiting. The method 800 may be altered, e.g., by having stages added, removed, rearranged, combined, performed concurrently, and/or having single stages split into multiple stages.

At stage 802, the method includes obtaining an indication of oscillator temperature information associated with one or more radio frequency signals. An AP 300, including the processor 310 and the transceiver 315, is a means for obtaining the indication of oscillator temperature information. In an example, a wireless node may be configured to transmit the one or more radio frequency signals. For example, the second node in the XO calibration packet exchange 700 and the radio frequency signals may be measurement packets 702a-d. The wireless node may be configured with a thermistor, or other temperature sensing device, disposed proximate to a local crystal oscillator (XO). The temperature information may be disposed in packets within the radio frequency signals. In an example, a network resource, such as a server, may be configured to receive the oscillator temperature and frequency offset information as reported by a wireless node to generate the calibration information described herein.

At stage 804, the method includes determining a frequency offset value based at least in part on the one or more radio frequency signals. The AP 300, including the processor 310 and the transceiver 315, is a means for determining the radio frequency offset value. In an example, the frequency offset value may be determined based on comparing the carrier frequency of the received RF signals to a local oscillator frequency (e.g., using correlation or cross-correlation techniques). In an example, the offset value may be based on data included in the radio frequency signals. Other techniques as known in the art may be used to determine the frequency offset value associated with the RF signals. In an example, referring to FIG. 7, a wireless node may be configured to obtain a frequency offset value for one or more packets, such as the frequency offsets 710a-c obtained by the second node.

At stage 806, the method includes determining a local oscillator temperature value. The AP 300, including the temperature sensor 404, is a means for determining the local oscillator temperature value. In an example, each wireless node involved with the calibration procedure may include a thermistor proximate to a local XO. In an example, referring to FIG. 7, a wireless node may be configured to obtain a temperature measurement during the reception of one or more packets, such as the XO temperatures 708a-c obtained by the second node.

At stage 808, the method includes determining a frequency correction value based at least in part on the local oscillator temperature value, the frequency offset value, and the indication of oscillator temperature information. The AP 300, including the processor 310, is a means for determining the frequency correction value. In an example, referring to FIG. 7, when the second packet is received (e.g., the second receive packet 706b), the second node has the temperature of first node's XO during packet 1 (e.g., the first temperature value 704a), the temperature of the second node's XO during the first packet (e.g., the first XO temperature 708a), and the frequency offset between the two nodes during packet 1 (e.g., the first frequency offset 710a). Equations (1)-(21) may be used to generate the frequency correction value described in equation (22).

At stage 810, the method includes transmitting a calibration report to a wireless node. The AP 300, including the processor 310 and the transceiver 315, is a means for transmitting the calibration report. In an example, referring to FIG. 6A, the responder 604 may be configured to receive the measurement packets (e.g., the RF signals received at stage 802), generate the frequency correction value, and transmit a XO calibration report including the frequency correction value. In an example, the XO calibration report may include the local oscillator temperature value, the frequency offset value, and the oscillator temperature information, and the wireless node may be configured to compute the frequency correction value based on that data. In an example, the frequency offset information may utilized by the satellite receiver for satellite signal acquisition for a period of time in a range of 1 to 100 seconds in duration. The frequency offset information may be utilized to compensate for the instability in an XO to improve stability over long correlation times.

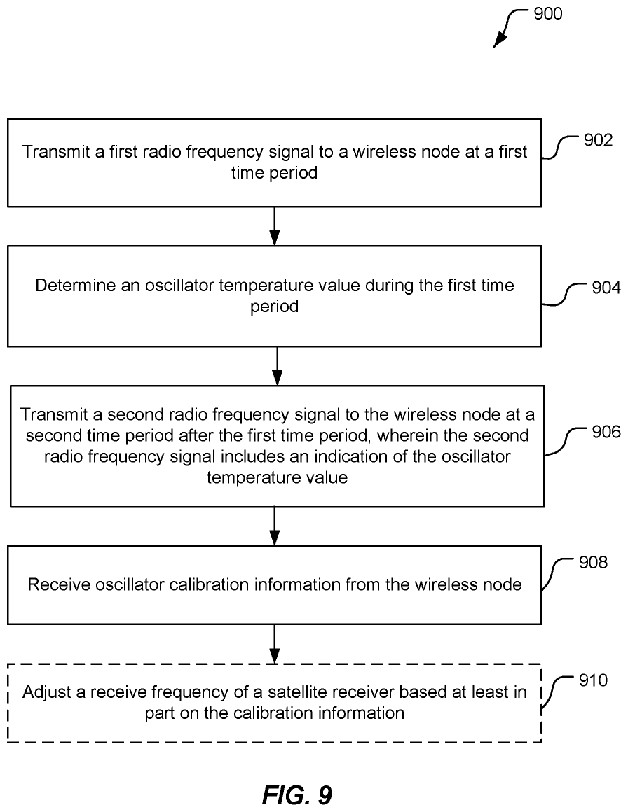

Referring to FIG. 9, with further reference to FIGS. 1-7, a method 900 for obtaining XO calibration information includes the stages shown. The method 900 is, however, an example and not limiting. The method 900 may be altered, e.g., by having stages added, removed, rearranged, combined, performed concurrently, and/or having single stages split into multiple stages. For example, adjusting a receive frequency in a GNSS receiver at stage 910 is optional.

At stage 902, the method includes transmitting a first radio frequency signal to a wireless node at a first time period. An AP 300, including the processor 310 and the transceiver 315, is a means for transmitting the first RF signal. Referring to FIG. 7, the first RF signal may be the first packet 702a transmitted by the first node. The RF signals may be transmitted via protocols such as WiFi, BE, BTE, and other device-to-device (D2D) protocols (e.g., NR Sidelink (SL)). Other RF technologies may also be used.

At stage 904, the method includes determining an oscillator temperature during the first time period. The AP 300, including the processor 310 and the temperature sensor 404, is a means for determining the oscillator temperature. In an example, the first node in FIG. 7 may include a thermistor or other temperature sensor disposed proximate to a XO in the transceiver 315. The processor 310 may be configured to obtain the first temperature value 704a when the first packet 702a is being transmitted.

At stage 906, the method includes transmitting a second radio frequency signal to the wireless node at a second time period after the first time period, wherein the second radio frequency signal includes an indication of the oscillator temperature value. The AP 300, including the processor 310 and the transceiver 315, is a means for transmitting the second RF signal. The first RF signal transmitted at stage 902, and the second RF signal are examples of measurement packets as described in FIGS. 6A and 6B. In an example, referring to FIG. 7, the first temperature value 704a may be included in the payload of the second packet 702b.

At stage 908, the method includes receiving oscillator calibration information from the wireless node. The AP 300, including the processor 310 and the transceiver 315, is a means for receiving oscillator calibration information. The wireless node may be configured to obtain local oscillator temperature information in the first and second time periods. The wireless node may also determine frequency offset values based on the first and second RF signals. The local oscillator temperature information, the frequency offset values, and the oscillator temperature value included in the second RF signal may be used to generate oscillator calibration information, such as frequency offset as described in equations (21) and (22). The wireless node may be configured to transmit a XO calibration report message including the oscillator calibration information. The oscillator calibration information may be used as a frequency offset with a XO. The XO may be configured for use with a communication modem and/or a GNSS receiver.

At stage 910, the method optionally includes adjusting a receive frequency of a satellite receiver based at least in part on the calibration information. The AP 300, including the processor 310 and the SPS receiver 317, is a means for adjusting the receive frequency of the satellite receiver. The correction described at equation (22) may be applied during GNSS receive operations based on a temperature measurement of the oscillator (e.g., XO).

Other examples and implementations are within the scope of the disclosure and appended claims. For example, due to the nature of software and computers, functions described above can be implemented using software executed by a processor, hardware, firmware, hardwiring, or a combination of any of these. Features implementing functions may also be physically located at various positions, including being distributed such that portions of functions are implemented at different physical locations. Components, functional or otherwise, shown in the figures and/or discussed herein as being connected or communicating with each other are communicatively coupled unless otherwise noted. That is, they may be directly or indirectly connected to enable communication between them.

As used herein, the singular forms “a,” “an,” and “the” include the plural forms as well, unless the context clearly indicates otherwise. For example, “a processor” may include one processor or multiple processors. The terms “comprises,” “comprising,” “includes,” and/or “including,” as used herein, specify the presence of stated features, integers, steps, operations, elements, and/or components, but do not preclude the presence or addition of one or more other features, integers, steps, operations, elements, components, and/or groups thereof.

As used herein, unless otherwise stated, a statement that a function or operation is “based on” an item or condition means that the function or operation is based on the stated item or condition and may be based on one or more items and/or conditions in addition to the stated item or condition.

Also, as used herein, “or” as used in a list of items (possibly prefaced by “at least one of” or prefaced by “one or more of”) indicates a disjunctive list such that, for example, a list of “at least one of A, B, or C,” or a list of “one or more of A, B, or C” or a list of A or B or C” means A, or B, or C, or AB (A and B), or AC (A and C), or BC (B and C), or ABC (i.e., A and B and C), or combinations with more than one feature (e.g., AA, AAB, ABBC, etc.). Thus, a recitation that an item, e.g., a processor, is configured to perform a function regarding at least one of A or B, or a recitation that an item is configured to perform a function A or a function B, means that the item may be configured to perform the function regarding A, or may be configured to perform the function regarding B, or may be configured to perform the function regarding A and B. For example, a phrase of “a processor configured to measure at least one of A or B” or “a processor configured to measure A or measure B” means that the processor may be configured to measure A (and may or may not be configured to measure B), or may be configured to measure B (and may or may not be configured to measure A), or may be configured to measure A and measure B (and may be configured to select which, or both, of A and B to measure). Similarly, a recitation of a means for measuring at least one of A or B includes means for measuring A (which may or may not be able to measure B), or means for measuring B (and may or may not be configured to measure A), or means for measuring A and B (which may be able to select which, or both, of A and B to measure). As another example, a recitation that an item, e.g., a processor, is configured to at least one of perform function X or perform function Y means that the item may be configured to perform the function X, or may be configured to perform the function Y, or may be configured to perform the function X and to perform the function Y. For example, a phrase of “a processor configured to at least one of measure X or measure Y” means that the processor may be configured to measure X (and may or may not be configured to measure Y), or may be configured to measure Y (and may or may not be configured to measure X), or may be configured to measure X and to measure Y (and may be configured to select which, or both, of X and Y to measure). Substantial variations may be made in accordance with specific requirements. For example, customized hardware might also be used, and/or particular elements might be implemented in hardware, software (including portable software, such as applets, etc.) executed by a processor, or both. Further, connection to other computing devices such as network input/output devices may be employed.

The systems and devices discussed above are examples. Various configurations may omit, substitute, or add various procedures or components as appropriate. For instance, features described with respect to certain configurations may be combined in various other configurations. Different aspects and elements of the configurations may be combined in a similar manner. Also, technology evolves and, thus, many of the elements are examples and do not limit the scope of the disclosure or claims.

A wireless communication system is one in which communications are conveyed wirelessly, i.e., by electromagnetic and/or acoustic waves propagating through atmospheric space rather than through a wire or other physical connection. A wireless communication network may not have all communications transmitted wirelessly, but is configured to have at least some communications transmitted wirelessly. Further, the term “wireless communication device,” or similar term, does not require that the functionality of the device is exclusively, or even primarily, for communication, or that the device be a mobile device, but indicates that the device includes wireless communication capability (one-way or two-way), e.g., includes at least one radio (each radio being part of a transmitter, receiver, or transceiver) for wireless communication.

Specific details are given in the description to provide a thorough understanding of example configurations (including implementations). However, configurations may be practiced without these specific details. For example, well-known circuits, processes, algorithms, structures, and techniques have been shown without unnecessary detail in order to avoid obscuring the configurations. This description provides example configurations, and does not limit the scope, applicability, or configurations of the claims. Rather, the preceding description of the configurations provides a description for implementing described techniques. Various changes may be made in the function and arrangement of elements without departing from the scope of the disclosure.

The terms “processor-readable medium,” “machine-readable medium,” and “computer-readable medium,” as used herein, refer to any medium that participates in providing data that causes a machine to operate in a specific fashion. Using a computing platform, various processor-readable media might be involved in providing instructions/code to processor(s) for execution and/or might be used to store and/or carry such instructions/code (e.g., as signals). In many implementations, a processor-readable medium is a physical and/or tangible storage medium. Such a medium may take many forms, including but not limited to, non-volatile media and volatile media. Non-volatile media include, for example, optical and/or magnetic disks. Volatile media include, without limitation, dynamic memory.

A statement that a value exceeds (or is more than or above) a first threshold value is equivalent to a statement that the value meets or exceeds a second threshold value that is slightly greater than the first threshold value, e.g., the second threshold value being one value higher than the first threshold value in the resolution of a computing system. A statement that a value is less than (or is within or below) a first threshold value is equivalent to a statement that the value is less than or equal to a second threshold value that is slightly lower than the first threshold value, e.g., the second threshold value being one value lower than the first threshold value in the resolution of a computing system.

Implementation examples are described in the following numbered clauses:

Clause 1. A method for generating XO calibration information, comprising: obtaining an indication of oscillator temperature information associated with one or more radio frequency signals; determining a frequency offset value based at least in part on the radio frequency signals; determining a local oscillator temperature value; determining a frequency correction value based at least in part on the local oscillator temperature value, the frequency offset value, and the indication of oscillator temperature information; and transmitting a calibration report to a wireless node.

Clause 2. The method of clause 1, wherein determining the local oscillator temperature value is based on a thermal sensor disposed proximate to a crystal oscillator.

Clause 3. The method of clause 1, wherein radio frequency signals comprise one or more data packets and the indication of oscillator temperature information is included in the one or more data packets.

Clause 4. The method of clause 1, wherein determining the frequency offset value is based on comparing a frequency of the received radio frequency signals to a local oscillator frequency.

Clause 5. The method of clause 1, further comprising receiving a XO calibration request message from the wireless node, and transmitting a XO calibration acknowledgement frame to the wireless node prior to receiving the radio frequency signals from the wireless node.

Clause 6. The method of clause 1, further comprising transmitting one or more measurement packets including oscillator temperature information to the wireless node.

Clause 7. The method of clause 6, further comprising receiving a XO calibration report including frequency offset information from the wireless node.

Clause 8. The method of clause 7, further comprising adjusting a receive frequency of a satellite receiver based at least in part on the frequency offset information.

Clause 9. A method for obtaining XO calibration information, comprising: transmitting a first radio frequency signal to a wireless node at a first time period; determining an oscillator temperature value during the first time period; transmitting a second radio frequency signal to the wireless node at a second time period after the first time period, wherein the second radio frequency signal includes an indication of the oscillator temperature value; and receiving oscillator calibration information from the wireless node.

Clause 10. The method of clause 9, further comprising adjusting a receive frequency of a satellite receiver based at least in part on the calibration information.

Clause 11. The method of clause 9, wherein determining the oscillator temperature value is based on a thermal sensor disposed proximate to a crystal oscillator.

Clause 12. The method of clause 9, further comprising transmitting a XO calibration request message to the wireless node, and receiving a XO calibration acknowledgement frame from the wireless node prior to transmitting the first radio frequency signal to the wireless node.

Clause 13. The method of clause 9, further comprising receiving one or more measurement packets including oscillator temperature information from the wireless node at a third time period.

Clause 14. The method of clause 13, further comprising determining the oscillator temperature value during the third time period.

Clause 15. The method of clause 13, further comprising determining frequency offset information based at least in part on receiving the one or more measurement packets.

Clause 16. The method of clause 15, further comprising: determining a frequency correction value based at least in part on the oscillator temperature information in the one or more measurement packets, the oscillator temperature value during the third time period, and the frequency offset information; and transmitting the frequency correction value to the wireless node.

Clause 17. An apparatus, comprising: at least one memory; at least one thermal sensor; at least one transceiver; at least one processor communicatively coupled to the at least one memory, the at least one thermal sensor, and the at least one transceiver, and configured to: obtain an indication of oscillator temperature information associated with one or more radio frequency signals; determine a frequency offset value based at least in part on the radio frequency signals; determine a local oscillator temperature value with the at least one thermal sensor; determine a frequency correction value based at least in part on the local oscillator temperature value, the frequency offset value, and the indication of oscillator temperature information; and transmit a calibration report to a wireless node.

Clause 18. The apparatus of clause 17, wherein the at least one thermal sensor is disposed proximate to a crystal oscillator in the at least one transceiver.

Clause 19. The apparatus of clause 17, wherein the one or more radio frequency signals comprise one or more data packets and the indication of oscillator temperature information is included in the one or more data packets.

Clause 20. The apparatus of clause 17, wherein the at least one processor is further configured to determine the frequency offset value based on comparing a frequency of the received radio frequency signals to a local oscillator frequency.

Clause 21. The apparatus of clause 17, wherein the at least one processor is further configured to receive a XO calibration request message from the wireless node, and transmit a XO calibration acknowledgement frame to the wireless node prior to receiving the radio frequency signals from the wireless node.

Clause 22. The apparatus of clause 17, wherein the at least one processor is further configured to transmit one or more measurement packets including oscillator temperature information to the wireless node.

Clause 23. The apparatus of clause 22, wherein the at least one processor is further configured to receive a XO calibration report including frequency offset information from the wireless node.

Clause 24. The apparatus of clause 23, further comprising a satellite receiver, wherein the at least one processor is further configured to adjust a receive frequency of the satellite receiver based at least in part on the frequency offset information.

25. An apparatus, comprising: at least one memory; at least one thermal sensor; at least one transceiver; at least one processor communicatively coupled to the at least one memory, the at least one thermal sensor, and the at least one transceiver, and configured to: transmit a first radio frequency signal to a wireless node at a first time period; determine an oscillator temperature value with the at least one thermal sensor during the first time period; transmit a second radio frequency signal to the wireless node at a second time period after the first time period, wherein the second radio frequency signal includes an indication of the oscillator temperature value; and receive oscillator calibration information from the wireless node.

Clause 26. The apparatus of clause 25, further comprising a satellite receiver, wherein the at least one processor is further configured to adjust a receive frequency of the satellite receiver based at least in part on the calibration information.

Clause 27. The apparatus of clause 25, wherein the at least one thermal sensor is disposed proximate to a crystal oscillator in the at least one transceiver.

Clause 28. The apparatus of clause 25, wherein the at least one processor is further configured to transmit a XO calibration request message to the wireless node, and receive a XO calibration acknowledgement frame from the wireless node prior to transmitting the first radio frequency signal to the wireless node.

Clause 29. The apparatus of clause 25, wherein the at least one processor is further configured to receive one or more measurement packets including oscillator temperature information from the wireless node at a third time period.

Clause 30. The apparatus of clause 29, wherein the at least one processor is further configured to determine the oscillator temperature value during the third time period.

Clause 31. The apparatus of clause 30, wherein the at least one processor is further configured to determine frequency offset information based at least in part on receiving the one or more measurement packets.

Clause 32. The apparatus of clause 31, wherein the at least one processor is further configured to: determine a frequency correction value based at least in part on the oscillator temperature information in the one or more measurement packets, the oscillator temperature value during the third time period, and the frequency offset information; and transmit the frequency correction value to the wireless node.

Clause 33. An apparatus for generating XO calibration information, comprising: means for receiving radio frequency signals from a wireless node, wherein the radio frequency signals include an indication of oscillator temperature information; means for determining a frequency offset value based at least in part on the radio frequency signals; means for determining a local oscillator temperature value; means for determining a frequency correction value based at least in part on the local oscillator temperature value, the frequency offset value, and the indication of oscillator temperature information; and means for transmitting a calibration report to the wireless node.

Clause 34. An apparatus for obtaining XO calibration information, comprising: means for transmitting a first radio frequency signal to a wireless node at a first time period; means for determining an oscillator temperature value during the first time period; means for transmitting a second radio frequency signal to the wireless node at a second time period after the first time period, wherein the second radio frequency signal includes an indication of the oscillator temperature value; and means for receiving oscillator calibration information from the wireless node.

Clause 35. A non-transitory processor-readable storage medium comprising processor-readable instructions configured to cause one or more processors to generate XO calibration information, comprising code for: receiving radio frequency signals from a wireless node, wherein the radio frequency signals include an indication of oscillator temperature information; determining a frequency offset value based at least in part on the radio frequency signals; determining a local oscillator temperature value; determining a frequency correction value based at least in part on the local oscillator temperature value, the frequency offset value, and the indication of oscillator temperature information; and transmitting a calibration report to the wireless node.

Clause 36. A non-transitory processor-readable storage medium comprising processor-readable instructions configured to cause one or more processors to obtain XO calibration information, comprising code for: transmitting a first radio frequency signal to a wireless node at a first time period; determining an oscillator temperature value during the first time period; transmitting a second radio frequency signal to the wireless node at a second time period after the first time period, wherein the second radio frequency signal includes an indication of the oscillator temperature value; and receiving oscillator calibration information from the wireless node.

1. A method for generating XO calibration information, comprising:
obtaining an indication of oscillator temperature information associated with one or more radio frequency signals;
determining a frequency offset value based at least in part on the one or more radio frequency signals;
determining a local oscillator temperature value;
determining a frequency correction value based at least in part on the local oscillator temperature value, the frequency offset value, and the indication of oscillator temperature information; and
transmitting a calibration report to a wireless node.

2. The method of claim 1, wherein determining the local oscillator temperature value is based on a thermal sensor disposed proximate to a crystal oscillator.

3. The method of claim 1, wherein the one or more radio frequency signals comprise one or more data packets and the indication of oscillator temperature information is included in the one or more data packets.

4. The method of claim 1, wherein determining the frequency offset value is based on comparing a frequency of the one or more radio frequency signals to a local oscillator frequency.

5. The method of claim 1, further comprising receiving a XO calibration request message from the wireless node, and transmitting a XO calibration acknowledgement frame to the wireless node prior to obtaining the indication of oscillator temperature information.

6. The method of claim 1, further comprising transmitting one or more measurement packets including oscillator temperature information to the wireless node.

7. The method of claim 6, further comprising receiving a XO calibration report including frequency offset information from the wireless node.

8. The method of claim 7, further comprising adjusting a receive frequency of a satellite receiver based at least in part on the frequency offset information.

9. The method of claim 8, wherein the frequency offset information is utilized by the satellite receiver for satellite signal acquisition for a period of time in a range of 1 to 100 seconds in duration.

10. An apparatus, comprising:
at least one memory;
at least one thermal sensor;
at least one transceiver;
at least one processor communicatively coupled to the at least one memory, the at least one thermal sensor, and the at least one transceiver, and configured to:
obtain an indication of oscillator temperature information associated with one or more radio frequency signals;
determine a frequency offset value based at least in part on the one or more radio frequency signals;
determine, via the at least one thermal sensor, a local oscillator temperature value;
determine a frequency correction value based at least in part on the local oscillator temperature value, the frequency offset value, and the indication of oscillator temperature information; and
transmit a calibration report to a wireless node.

11. The apparatus of claim 10, wherein the at least one thermal sensor is disposed proximate to a crystal oscillator in the at least one transceiver.

12. The apparatus of claim 10, wherein the one or more radio frequency signals comprise one or more data packets and the indication of oscillator temperature information is included in the one or more data packets.

13. The apparatus of claim 10, wherein the at least one processor is further configured to determine the frequency offset value based on comparing a frequency of the one or more radio frequency signals to a local oscillator frequency.

14. The apparatus of claim 10, wherein the at least one processor is further configured to receive a XO calibration request message from the wireless node, and transmit a XO calibration acknowledgement frame to the wireless node prior to receiving the one or more radio frequency signals.

15. The apparatus of claim 10, wherein the at least one processor is further configured to transmit one or more measurement packets including oscillator temperature information to the wireless node.

16. The apparatus of claim 15, wherein the at least one processor is further configured to receive a XO calibration report including frequency offset information from the wireless node.

17. The apparatus of claim 16, further comprising a satellite receiver, wherein the at least one processor is further configured to adjust a receive frequency of the satellite receiver for based at least in part on the frequency offset information.

18. The apparatus of claim 17, wherein the at least one processor is further configured to utilize the frequency offset information for satellite signal acquisition for a period of time in a range of 1 to 100 seconds in duration.

19. An apparatus for generating XO calibration information, comprising:
means for obtaining an indication of oscillator temperature information associated with one or more radio frequency signals;
means for determining a frequency offset value based at least in part on the one or more radio frequency signals;
means for determining a local oscillator temperature value;
means for determining a frequency correction value based at least in part on the local oscillator temperature value, the frequency offset value, and the indication of oscillator temperature information; and
means for transmitting a calibration report to a wireless node.

20. The apparatus of claim 19, further comprising:
means for receiving a XO calibration report including frequency offset information from the wireless node; and
means for adjusting a receive frequency of a satellite receiver based at least in part on the frequency offset information, wherein the frequency offset information is utilized by the satellite receiver for satellite signal acquisition for a period of time in a range of 1 to 100 seconds in duration.
